(19) United States
(12) Patent Application Publication
(10) Pub. No.: US 2008/0054945 A1
(43) Pub. Date: Mar. 6, 2008

(54) Method and apparatus for loss-of-clock detection

(76) Inventor: Tony S. El-Kik, Allentown, PA (US)

Correspondence Address: RYAN, MASON & LEWIS, LLP, 1300 POST ROAD, SUITE 205, FAIRFIELD, CT, 06824, US

(21) Appl. No.: 11/513,812

(22) Filed: Aug. 31, 2006

(51) Int. Cl. H03K 19/00

(52) U.S. Cl. 326/93

(57) ABSTRACT

Methods and apparatus are provided for loss-of-clock detection. A loss of a clock signal is detected by delaying the clock signal using one or more delay elements; and applying an output of the one or more delay elements to at least one logic gate having a plurality of inputs, wherein the at least one logic gate has a predefined binary output value when each of the inputs to the at least one logic gate have a predefined input binary value to detect when the clock signal is in a fixed binary position. The at least one logic gate can be an AND gate (or a NOR gate having inverted inputs) to detect when the clock signal is in a fixed high position. The at least one logic gate can also be a NOR gate (or an AND gate having inverted inputs) to detect when the clock signal is in a fixed low position. A third logic gate, such as an OR gate, can detect when at least one of two logic gates has a predefined binary output value.

### FIELD OF THE INVENTION

The present invention is related to techniques for loss-of-clock detection and, more particularly, to digital techniques for loss-of-clock detection.

### BACKGROUND OF THE INVENTION

Many circuits depend on the presence of a clock signal, for example, to drive digital logic within these circuits. If the clock signal is disrupted, the digital circuits that are triggered off of the clock signal may not function properly. The disruption of the clock signal is often referred to as a “loss of clock” condition. A number of loss-of-clock (LOC) detectors have been disclosed or suggested that monitor a clock signal and determine when the clock signal is disrupted. For example, the loss of clock detection can warn the system to go into a power down mode and stay in that state until the clock is present again. This will help the device to power down gracefully.

FIG. 1 illustrates a conventional loss-of-clock detector 100. The loss-of-clock detector 100 shown in FIG. 1 is an analog clock circuit comprising an inverter 110, two n-FET transistors 120-A, 120-B, two resistors, 130-R, 140-R, two capacitors 130-C, 140-C, and a two input OR gate 150. The loss-of-clock detector 100 works by charging the top capacitor 130-C when the clock is active high. If the applied clock signal toggles to “0,” then the signal “N1” is pulled Low. If the clock stays high then N1 goes to “1”. Similarly, the bottom capacitor 140-C is charged when the clock is active low. If the clock toggles to “1,” then the signal “N2” is pulled Low. If the clock stays low then N2 goes to “1”. The N1 and N2 signals are applied to the OR gate 150. In this manner, when either “N1” or “N2” is high, then the OR gate 150 causes the loss of clock signal goes to “1,” indicating that the clock is no longer toggling between the two values and is maintaining a constant value (Low or High).

While the loss-of-clock detector 100 can effectively determine when the clock signal is disrupted, it suffers from a number of limitations, which if overcome, could further improve the reliability and utility of loss-of-clock detectors. In particular, the detection of the absence of the clock depends on the resistor-capacitor (RC) value of the two RC filters 130, 140 that could vary with the input clock duty cycle, process parameters and the ambient temperature. Generally, the RC values are chosen so that the resulting RC time constant is higher than the expected time between transitions or edges of the clock. Manufacturing variations in the values of R or C, which can be, for example, as large as 50% of the nominal component values, or variations of R with chip temperature, which can be, for example, as large as 20% over the specified operating temperature range of most integrated circuits, lead to a large detection time window. In addition, since R and C are fixed quantities, the RC time constant does not vary with the frequency of the input clock.

A need therefore exists for a digital loss-of-clock detector. A further need exists for a loss-of-clock detector that has a programmable speed and duty cycle. Yet another need exists for a loss-of-clock detector that does not need to be redesigned and migrated to a different library for each technology change, and that is not dependent on process parameter variations.

### SUMMARY OF THE INVENTION

Generally, methods and apparatus are provided in this invention for loss-of-clock detection. According to one aspect of the invention, a loss of a clock signal is detected by delaying the clock signal using one or more delay elements; and applying an output of the one or more delay elements to at least one logic gate having a plurality of inputs, wherein the at least one logic gate has a predefined binary output value when each of the inputs to the at least one logic gate have a predefined input binary value to detect when the clock signal is in a fixed binary position.

For example, the at least one logic gate can be an AND gate (or a NOR gate having inverted inputs) and the predefined input binary value is a high logic value that is used to detect when the clock signal is in a fixed high position. In a further variation, the at least one logic gate is a NOR gate (or an AND gate having inverted inputs) and the predefined input binary value is a low logic value that is used to detect when the clock signal is in a fixed low position. The output of the plurality of delay elements can be applied to at least two logic gates and a third logic gate, such as an OR gate, to detect when at least one of the at least two logic gates has a predefined binary output value. In one exemplary embodiment, the plurality of delay elements has a total delay that exceeds a period of the clock signal.

A more complete understanding of the present invention, as well as further features and advantages of the present invention, will be obtained by reference to the following detailed description and drawings.

### BRIEF DESCRIPTION OF THE DRAWINGS

FIG. 1 illustrates a conventional loss-of-clock detector;

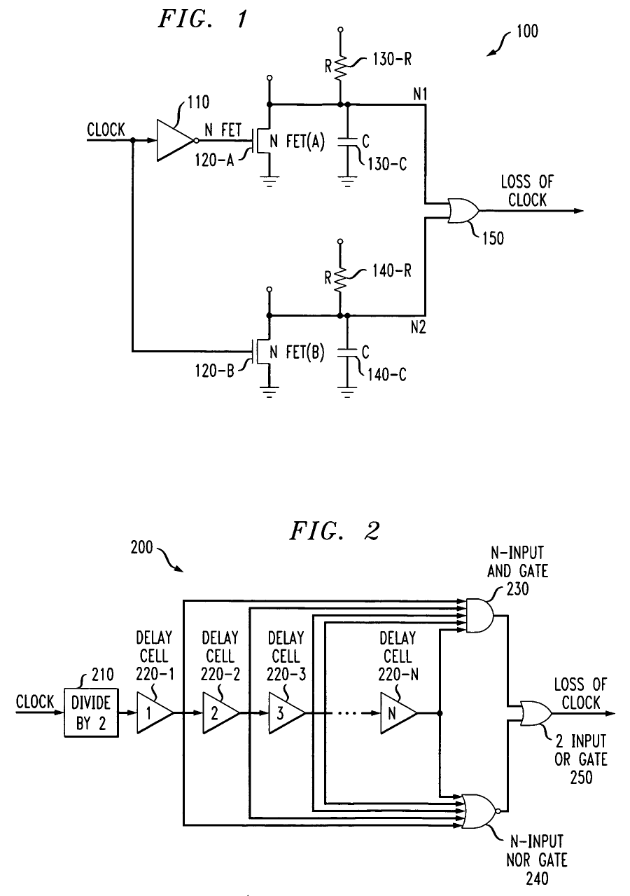

FIG. 2 illustrates a loss-of-clock detector that incorporates features of the present invention; and

FIGS. 3 and 4 illustrate various signals from the loss-of-clock detector of FIG. 2.

### DETAILED DESCRIPTION

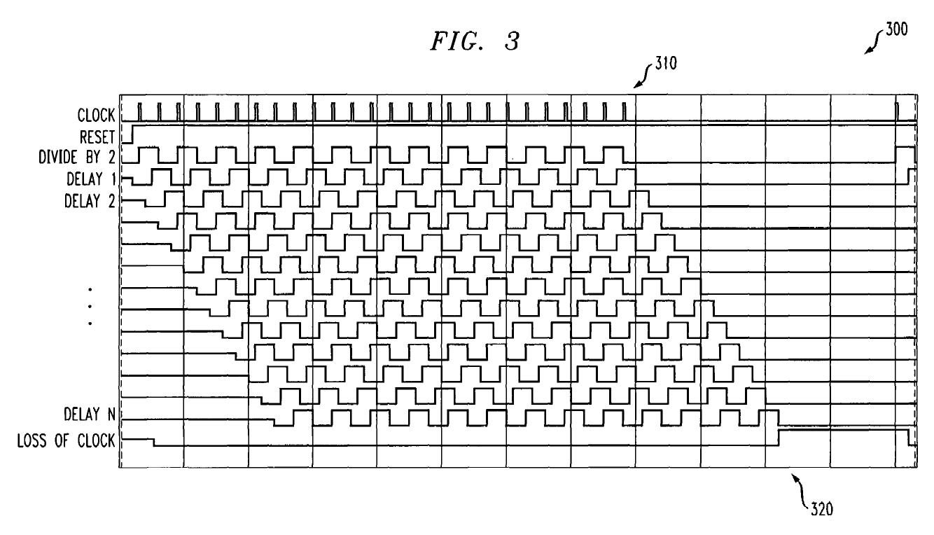

The present invention provides a digital loss-of-clock detector. The disclosed loss-of-clock detector provides a programmable speed and duty cycle. FIG. 2 illustrates an exemplary loss-of-clock detector 200 that incorporates features of the present invention. The loss-of-clock detector 200 shown in FIG. 2 is a digital clock circuit that includes a divide by 2 counter 210, N delay cells 220-1 through 220-N, an N-input AND gate 230, an N-input NOR gate 240 and two input OR gate 250. The divide-by-2 circuit 210 converts, for example, a 10-90% duty cycle clock (low value for 90% of period and high value for 10% of period) into a 50% duty cycle clock in a known manner. Through the use of the divide-by-2 circuit 210, the clock is passed through the delay cell chain 220 and does not get filtered by the delay chain 220.

The outputs of the N delay element(s) 220 are applied to the N-input NOR gate 240 to detect when the input clock is stuck in a low position and are applied to the N-input AND gate 230 to detect when the input clock is stuck in a high position. The outputs of the NOR gate 240 and the AND gate 230 are applied to the two input OR gate 250 to produce the loss of clock signal that is high when there is no clock present. It is noted that, in alternative embodiments of the invention, the NOR gate 240 can be replaced with inverted inputs to an AND gate (not shown) and the AND gate 230 can be replaced with inverted inputs to a NOR gate (not shown). Further, in some embodiments of the invention, the delay element(s) 220 are implemented as separate delay components/circuits, while in other embodiments, the delay element(s) 220 may be implemented as a single delay component, having multiple outputs providing different periods of signal delay from the input of the delay element(s) 220.

In an exemplary implementation where a loss of clock is detected within one clock period, the length of the delay cell chain 220 should preferably be higher than the period of the input clock. For example, assuming a clock period of 10 nanoseconds, and if each delay element 220-i has an absolute delay of 1 nanosecond, then the delay chain 220 should comprise at least 11 delay elements. In this manner, the outputs of each delay element in the delay chain 220 cover the full clock period. If the clock is stuck in a high position, the outputs of each delay element will be high, and the output of the AND gate 230 will be high. Likewise, if the clock is stuck in a low position, the outputs of each delay element will be low, and the output of the NOR gate 240 will be high. If the output of either the NOR gate 240 or the AND gate 230 are high, the output of the OR gate 250 will be high.

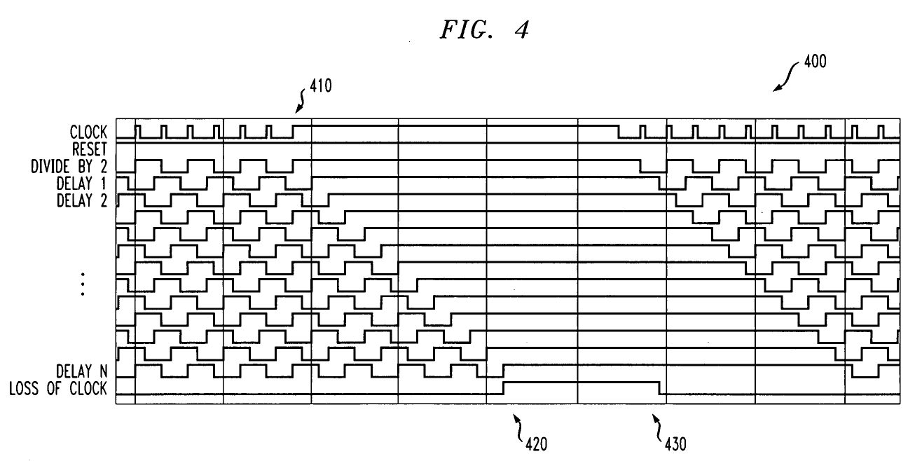

FIG. 3 illustrates various signals 300 from the loss-of-clock detector 200 of FIG. 2. The exemplary input clock signal has a 10%-90% duty cycle. In the example of FIG. 3, the clock signal becomes stuck low at a time 310. After the clock signal becomes stuck low, the output of each delay element 220 successively stays low, and the loss of clock signal is set at a time 320 when the output of each delay element in the chain 220 is low.

FIG. 4 illustrates various signals 400 from the loss-of-clock detector 200 of FIG. 2. The exemplary input clock signal again has a 90%- 10% duty cycle. In the example of FIG. 4, the clock signal becomes stuck high at a time 410. After the clock signal becomes stuck high, the output of each delay element 220 successively stays high, and the loss of clock signal is set at a time 420 when the output of each delay element in the chain 220 is high. The loss of clock signal is reset at point 430 because the clock started to toggle again and the Delay 1 went to “0” and eventually all the delayed signals “Delay2, Delay3, . . . ” started to toggle again. (All signals are not “1” anymore so the output of the AND gate 230 is not “1” anymore).

In the fabrication of an integrated circuit, a plurality of identical die are typically formed in a repeated pattern on a surface of the wafer. In the implementation of one present embodiment of this invention, one or more of the die includes a device, or circuit, for detecting the loss of a clock, as described herein, and may include other structures or circuits. The individual die are cut or diced from the wafer, then packaged as an integrated circuit. One skilled in the art would know how to dice wafers and package die to produce integrated circuits. Integrated circuits so manufactured are considered part of this invention.

While exemplary embodiments of the present invention have been described with respect to digital logic blocks, as would be apparent to one skilled in the art, various functions may be implemented in the digital domain as processing steps in a software program, in hardware by circuit elements or state machines, or in combination of both software and hardware. Such software may be employed in, for example, a digital signal processor, micro-controller, or general-purpose computer. Such hardware and software may be embodied within circuits implemented within an integrated circuit.

Thus, the functions of the present invention can be embodied in the form of methods and apparatuses for practicing those methods. One or more aspects of the present invention can be embodied in the form of program code, for example, whether stored in a storage medium, loaded into and/or executed by a machine, or transmitted over some transmission medium, wherein, when the program code is loaded into and executed by a machine, such as a computer, the machine becomes an apparatus for practicing the invention. When implemented on a general-purpose processor, the program code segments combine with the processor to provide a device that operates analogously to specific logic circuits.

It is to be understood that the embodiments and variations shown and described herein are merely illustrative of the principles of this invention and that various modifications may be implemented by those skilled in the art without departing from the scope and spirit of the invention.

I claim:

1. A method for detecting a loss of a clock signal, comprising:
delaying said clock signal using one or more delay elements; and
applying an output of said one or more delay elements to at least one logic gate having a plurality of inputs, wherein said at least one logic gate has a predefined binary output value when each of said inputs to said at least one logic gate have a predefined input binary value to detect when said clock signal is in a fixed binary position.

2. The method of claim 1, wherein the at least one logic gate is an AND gate and the predefined input binary value is a high logic value to detect when said clock signal is in a fixed high position.

3. The method of claim 1, wherein the at least one logic gate is a NOR gate having inverted inputs and the predefined input binary value is a high logic value to detect when said clock signal is in a fixed high position.

4. The method of claim 1, wherein the at least one logic gate is a NOR gate and the predefined input binary value is a low logic value to detect when said clock signal is in a fixed low position.

5. The method of claim 1, wherein the at least one logic gate is an AND gate having inverted inputs and the predefined input binary value is a low logic value to detect when said clock signal is in a fixed low position.

6. The method of claim 1, wherein said output of said one or more delay elements are applied to at least two logic gates and said method further comprising the step of applying an output of said at least two logic gates to a third logic gate that detects when at least one of said at least two logic gates has a predefined binary output value.

7. The method of claim 6, wherein said third logic gate is an OR gate.

8. The method of claim 1, wherein said one or more delay elements has a total delay that exceeds a period of said clock signal.

9. The method of claim 1, further comprising the step of dividing said clock signal.

10. A circuit for detecting a loss of a clock signal, comprising:
one or more delay elements for delaying said clock signal; and
at least one logic gate having a plurality of inputs each connected to at least one output of said one or more delay elements, wherein said at least one logic gate has a predefined binary output value when each of said inputs to said at least one logic gate have a predefined input binary value to detect when said clock signal is in a fixed binary position.

11. The circuit of claim 10, wherein the at least one logic gate is an AND gate and the predefined input binary value is a high logic value to detect when said clock signal is in a fixed high position.

12. The circuit of claim 10, wherein the at least one logic gate is a NOR gate having inverted inputs and the predefined input binary value is a high logic value to detect when said clock signal is in a fixed high position.

13. The circuit of claim 10, wherein the at least one logic gate is a NOR gate and the predefined input binary value is a low logic value to detect when said clock signal is in a fixed low position.

14. The circuit of claim 10, wherein the at least one logic gate is an AND gate having inverted inputs and the predefined input binary value is a low logic value to detect when said clock signal is in a fixed low position.

15. The circuit of claim 10, wherein said output of said one or more delay elements are applied to at least two logic gates and further comprising a third logic gate to process an output of said at least two logic gates, wherein said third logic gate detects when at least one of said at least two logic gates has a predefined binary output value.

16. The circuit of claim 15, wherein said third logic gate is an OR gate.

17. The circuit of claim 10, wherein said one or more delay elements has a total delay that exceeds a period of said clock signal.

18. The circuit of claim 10, further comprising the step of dividing said clock signal.

19. An integrated circuit, comprising:
a circuit for detecting a loss of a clock signal, comprising:
one or more delay elements for delaying said clock signal; and
at least one logic gate having a plurality of inputs each connected to at least one output of said one or more delay elements, wherein said at least one logic gate has a predefined binary output value when each of said inputs to said at least one logic gate have a predefined input binary value to detect when said clock signal is in a fixed binary position.

20. The integrated circuit of claim 19, wherein the at least one logic gate is an AND gate and the predefined input binary value is a high logic value to detect when said clock signal is in a fixed high position.

21. The integrated circuit of claim 19, wherein the at least one logic gate is a NOR gate having inverted inputs and the predefined input binary value is a high logic value to detect when said clock signal is in a fixed high position.

22. The integrated circuit of claim 19, wherein the at least one logic gate is a NOR gate and the predefined input binary value is a low logic value to detect when said clock signal is in a fixed low position.

23. The integrated circuit of claim 19, wherein the at least one logic gate is an AND gate having inverted inputs and the predefined input binary value is a low logic value to detect when said clock signal is in a fixed low position.

24. The integrated circuit of claim 19, wherein said output of said one or more delay elements are applied to at least two logic gates and further comprising a third logic gate to process an output of said at least two logic gates, wherein said third logic gate detects when at least one of said at least two logic gates has a predefined binary output value.
